(19) United States
(12) Patent Application Publication
(10) Pub. No.: US 2008/0111517 A1
(43) Pub. Date: May 15, 2008

(54) Charge Controller for DC-DC Power Conversion

(76) Inventors: John E. Pfeifer, Redding, CT (US); Fabio A.M. Pereira, Naugatuck, CT (US); Herbert E. Flynn, Sandy Hook, CT (US)

Correspondence Address: GORDON & JACOBSON, P.C., 60 LONG RIDGE ROAD, SUITE 407, STAMFORD, CT, 06902, US

(21) Appl. No.: 11/560,186

(22) Filed: Nov. 15, 2006

(51) Int. Cl. H02J 7/00; G05F 5/00; H01L 31/042

(52) U.S. Cl. 320/101; 323/299; 320/160; 136/244

(57) ABSTRACT

A charge controller that includes an input interface that receives input DC electrical signals. A converter section converts the input DC electrical signals to output DC electrical signals. Control means is operably coupled to the converter section. The control means includes means for operating the converter section at an estimated maximum power point of the input DC electrical signals. The estimated maximum power point is derived by a novel control scheme that quickly adapts to changing conditions and thus affords optimum energy harvest from the source and improved energy conversion efficiencies.

### BACKGROUND OF THE INVENTION

1. Field of the Invention

This invention relates broadly to charge controllers that perform DC-DC power conversion. More particularly, this invention relates to charge controllers for solar applications, including converting DC electrical energy provided by photo-voltaic means for charging electrochemical batteries and for direct output.

2. State of the Art

Photo-voltaic (PV) panels (sometimes referred to as photovoltaic modules) produce current at a specific voltage depending on the amount of solar radiation hitting the cells of the panel. The theoretical maximum amount of power from the sun at the earth's surface is about 1 KW per square meter at the equator on a clear day. To make the electrical power useful when the sun is not available, it must be stored, typically in batteries. The nature of the PV panels is that they have a specific Voltage×Current curve that changes with the temperature and on the amount of sunlight or the angle at which the sun strikes the panel. Higher temperatures lower the voltage and more sunlight increases the output current.

For increased system efficiency, it is desirable to operate PV panels at the voltage and current levels that produce the peak power, which is referred to as the Maximum Power Point. Loads such as batteries, on the other hand, have a need for voltage and current which is independent and often different from what the PV panel is producing. A charge controller (which can also be referred to as a charge regulator or regulator) is connected between the PV panel(s) and the batteries or load in order to deal with this miss-match. The charge controller performs DC-DC power conversion typically utilizing Pulse Width Modulation (PWM) control of the electrical energy produced by the PV panels in order to transform such energy into a suitable form. For example, for battery charging applications, the PWM control is used to adjust the voltage levels and current levels output the battery. More particularly, as the battery reaches full charge, the PWM control is used to limit the voltage level supplied to the battery such a not to the harm the battery (i.e., inhibiting the boiling of the electrolyte of the battery, which can destroy the battery).

Early charge controllers were only able to reduce the amount of voltage from the PV panels if too high for the batteries. Since the voltage from the PV panels would be lower at high temperatures, the PV panels had to be over sized to ensure that the minimum voltage at high temperatures would be at least as high as the battery to be charged plus voltage headroom enough to force current into the battery. At any temperature lower than the maximum, the excess voltage from the PV panels would have to be discarded by the charge controllers. Because PV panels are the most expensive component of the system, the need for extra (or larger) PV panels negatively impacted the cost-effectiveness of such PV power systems.

Newer and more efficient charger controllers have emerged that provide a better match between the PV panels and their load. Their goal is to use all the power from the PV panel(s) regardless of the voltage and current at any amount of insolation or at any temperature. The newer charge controllers employ a DC to DC converter section that is adapted to dynamically charge the battery (or to directly power a load) at the exact voltage and current that is most appropriate for that battery (or load). Although the newer charge controllers provide improved system efficiencies relative to the older models, they too often suffer from several shortcomings. More particularly, the charge controllers are slow to adapt to changing conditions of the PV panel(s) over the course of any given day, including low light conditions in the morning, evening and during cloud cover and also temperature changes sometimes associated with the changes in insolation. The edges of clouds create particularly issues because they cause a rapid change in lighting which may be followed by a relatively rapid change in temperature. Because they do not quickly adapt to changing conditions, the charge controllers have limited efficiency, which results in the need for extra (or larger) PV panels to be used for a given power output and high costs.

### SUMMARY OF THE INVENTION

It is therefore an object of the invention to provide a charge controller that quickly adapts to changing conditions and thus affords improved energy conversion efficiencies.

It is another object of the invention to provide such a charge controller which can be adapted for use with a wide range of PV panels.

It is a further object of the invention to provide such a charge controller which can be adapted for use with a wide range of DC loads including batteries for energy storage and DC-AC inverters for direct output.

In accord with these objects, which will be discussed in detail below, a charge controller is provided that includes an input interface that receives input DC electrical signals. A converter section converts the input DC electrical signals to output DC electrical signals. Control means is operably coupled to the converter section. The control means includes means for operating the converter section at an estimated maximum power point of the input DC electrical signals. The estimated maximum power point is derived by a control scheme that includes the following operations:
i) storing an input voltage level corresponding to the estimated maximum power point;
ii) varying the input voltage of the input DC electrical signals over a sequence of sample points from a first voltage level to a second voltage level, and deriving and storing an output current value of the output DC electrical signals at each sample point;
iii) selecting the maximum output current value from the output current values stored in ii), and identifying the particular input voltage level corresponding thereto; and
iv) varying the input voltage of the input DC electrical signals over a sequence of sample points from the second voltage level to the particular input voltage level identified in iii); and
v) updating the stored input voltage level corresponding to the estimated maximum power point to the particular input voltage level identified in iv).

In the preferred embodiment, for each given sample point in ii), the output current value for the sample point is derived by averaging a plurality of output current measurements at the given sample point, and the first and second voltage levels of ii) are derived from the measured open circuit voltage.

In another aspect of the invention, the control scheme carried out by the charge controller derives the estimated maximum power point by the following operations:
a) storing an input voltage level corresponding to the estimated maximum power point;
b) varying the input voltage of the input DC electrical signals over a number of sample points around the input voltage level stored in a), and deriving and storing an output current value of the output DC electrical signals at each sample point;
c) selecting the maximum output current value from the output current values stored in b) and identifying the particular input voltage level corresponding thereto; and
d) updating the stored input voltage level corresponding to the estimated maximum power point to the particular input voltage identified in c).
   The number of sample points in b) include a first plurality of sample points at input voltage values less than the input voltage level stored in a) and a second plurality of sample points at input voltage values greater than the input voltage level stored in a).

In the preferred embodiment, for each given sample point in b), the output current value for the sample point is derived by averaging a plurality of output current measurements at the given sample point, and the voltage differences between the sample points of b) is on the order of 100 millivolts.

In yet another aspect of the present invention, the control scheme carried out by the charge controller updates an input voltage level corresponding to an estimated maximum power point at a frequency of at least 500 Hz.

It will be appreciated that the maximum power point control operations of the present invention quickly adapt to changing conditions and thus afford improved energy conversion efficiencies.

In the illustrative embodiment, the converter section comprises a buck converter topology having input reservoir capacitance, at least one series switching element (e.g. an FET field effect transistor or IGBT insulated gate bipolar transistor), at least one synchronous rectifier switching element, at least one inductor, and gate drive circuitry that selectively switches the at least one series field effect transistor and the at least one synchronous rectifier field effect transistor between ON and OFF states in response to pulse width modulation control signals supplied thereto. The control means (e.g., a microcontroller, microprocessor, digital signal processor or other control logic) is operably coupled to the gate drive circuitry for varying the duty cycle of the pulse width modulation control signals supplied to the gate drive circuitry in order to vary the input voltage level of the input DC electrical signals.

In the preferred embodiment, the control scheme carried out by the control means includes an MPPT (Maximum Power Point Tracking) charging mode as well as a bulk charging mode, an absorption charging mode, and a float charging mode. In the MPPT charging mode, the control means regulates the input voltage of the input DC electrical signals such that it is maintained at the input voltage level corresponding to the estimated maximum power point as determined and stored by the control scheme. In the bulk charging mode, the control means regulates the output current of the output DC electrical signals such that it is limited to a predetermined maximum current limit. In the absorption charging mode, the control means regulates the output voltage of the output DC electrical signals such that it is maintained at a predetermined absorption charging mode voltage level. In the float charging mode, the control means regulates the output voltage of the output DC electrical signals such that it is maintained at a predetermined float charging mode voltage level.

Additional objects and advantages of the invention will become apparent to those skilled in the art upon reference to the detailed description taken in conjunction with the provided figures.

### BRIEF DESCRIPTION OF THE DRAWINGS

FIG. 1 is a block diagram of a solar electric generator system in which the present invention can be embodied.

FIG. 2 is a high-level schematic diagram of a charge controller in accordance with the present invention, which can be used as part of the solar electric generator system of FIG. 1 to convert the DC electrical signals generated by the photovoltaic array into a DC form suitable for supply to the DC load.

FIGS. 3A and 3B, collectively, is a flow chart illustrating automatic battery charging operations carried out by the charge controller of FIG. 2 in accordance with the present invention;

FIG. 4A is a pictorial illustration of the I-V curve of a typical photovoltaic module;

FIG. 4B is a pictorial illustration of exemplary scanning operations that are carried out by the charge controller of FIG. 2 for deriving an input voltage for estimated maximum power point conversion operations in accordance with the present invention;

FIG. 4C is a pictorial illustration of exemplary perturbation and observation operations that carried out by the charge controller of FIG. 2 for deriving the input voltage for estimated maximum power point conversion operations in accordance with the present invention; and

FIG. 5 is a flow chart illustrating operations carried out by the charge controller of FIG. 2 for deriving the input voltage for estimated maximum power point conversion operations in accordance with the present invention.

### DETAILED DESCRIPTION OF THE PREFERRED EMBODIMENTS

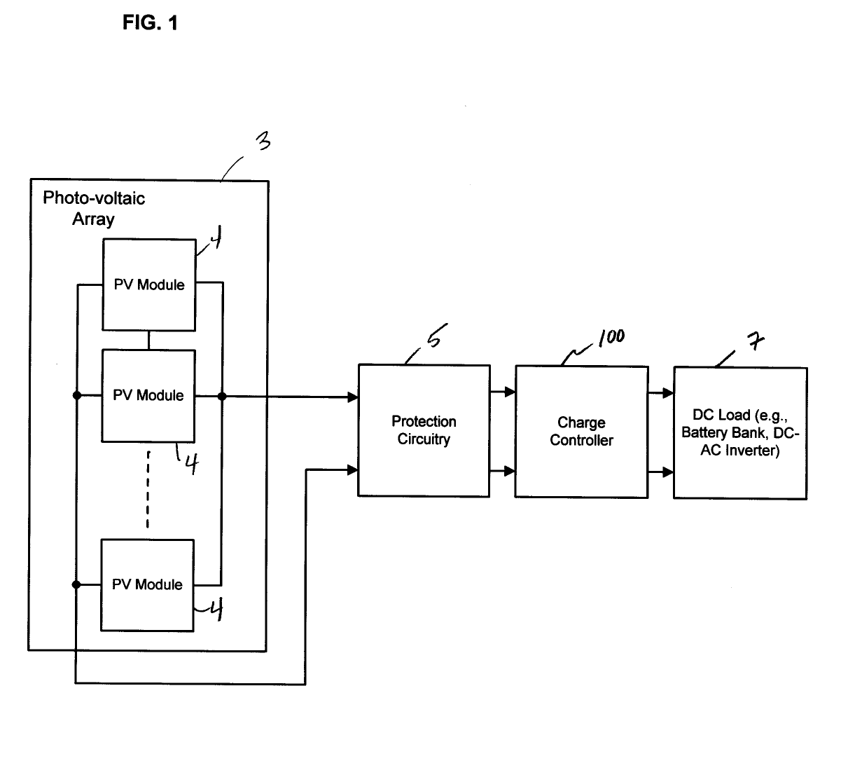

Turning now to FIG. 1, there is shown a functional block diagram of a solar power conversion system 1 which includes a photo-voltaic (PV) array 3 capable of generating direct current electricity from incident solar radiation. The photo-voltaic array 3 typically includes a number of PV modules 4 each comprising a number of series-connected solar cells. The PV modules 4 can be connected in a parallel configuration as shown so that sufficient power can be generated under minimum radiation conditions. The DC electrical signals generated by the PV array 3 are supplied to a number of series-connected components including protection circuitry 5, a charge controller 100 and a DC load 7. The protection circuitry 5 provides for protection against lightning strikes and other faults (typically by shunting fault current to ground through MOVs and the like) and can also provide protection for reverse-polarity faults. The protection circuitry 5 may also be responsible for limiting the maximum voltage which can otherwise be higher than the maximum allowable voltage for the components in the next stage. The open-circuit voltage (Voc) of the PV array 3 is about 20% to 30% higher than the operating voltage of the same array and the increased voltages at low temperatures represent the worst case. The charge controller 100 converts the DC electrical signals generated by the PV array 3 into DC electrical signal suitable for output to the DC load 7. The DC load 7 can be a bank of one or more batteries for energy storage and/or a DC-AC inverter for direct output.

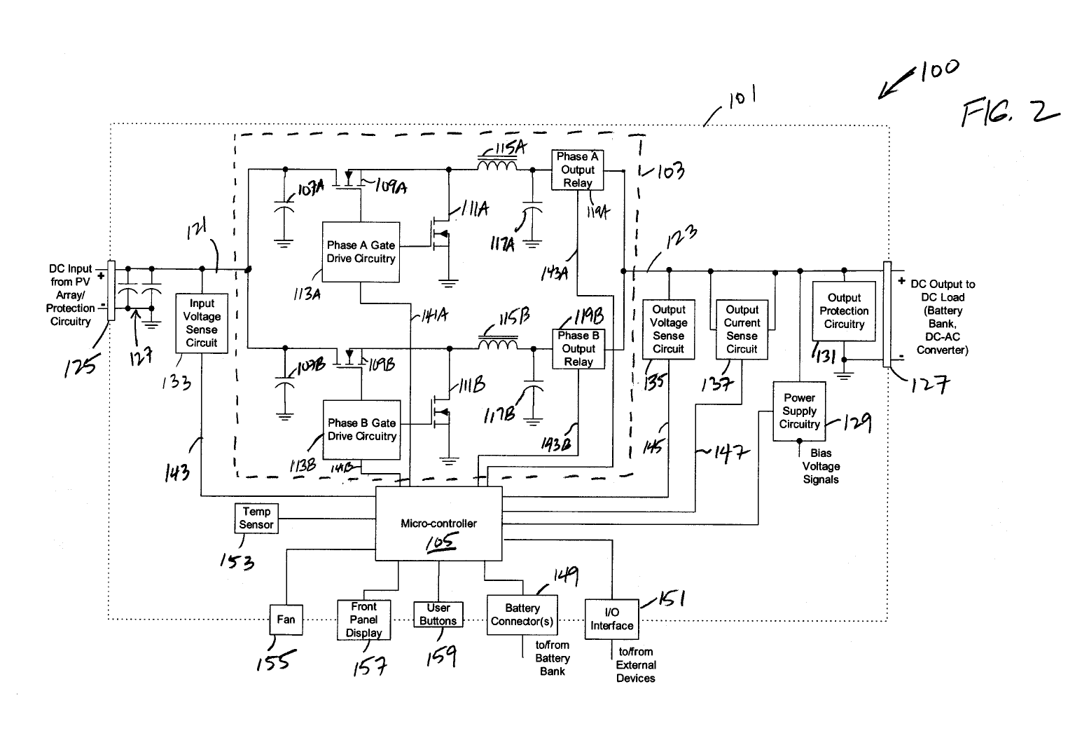

As shown in FIG. 2, the charge controller 100 includes a system housing 101 supports a synchronous buck converter section 103 interfaced to a microcontroller 105. The synchronous buck converter section 103 utilizes two switching elements (a series field effect transistor (FET) and a synchronous rectifier FET) to store energy into (and extract energy from) an inductor. The series FET and the synchronous rectifier FET are driven by gate drive circuitry to alternate between two states, a charging state and a discharging state. In the charging state, the series FET is turned ON and the synchronous rectifier FET is turned OFF such that the inductor is connected to a DC source voltage to store energy in the inductor. In the discharging state, the series FET is turned OFF and the synchronous rectifier FET is turned ON in order to discharge the energy stored in the inductor to the load. The gate drive circuitry that controls the operation of the series FET and the synchronous FET must prevent both switches from being turned on at the same time, which is a fault known as “shoot-through”. During operation, the cooperation of the switching action of the series FET, synchronous rectifier FET and the inductor reduce the DC source voltage level by a factor which is controlled by the duty cycle for the charging state of both FETs. This duty cycle is controlled by pulse width modulation (PWM) control signals supplied to the gate drive circuitry as is well known.

A multiphase synchronous buck converter is a topology whereby multiple buck converter circuits as described above are placed in parallel between the source voltage and the load and controlled to out of phase with each other. For example, two parallel circuits are set to switch such that one circuit is ON while the other is OFF. In other words, the two circuits are 180 degrees out of phase with one another. The primary advantage of this multiphase topology is that the load current can be split among the circuits or phases, thus allowing for increased load currents. Another equally important advantage is that the output ripple is reduced by the number of phases, thus allowing for easier filtering and lower output ripple. Each of these “phases” is turned ON at predetermined intervals over the switching period.

In the illustrative embodiment shown, the buck converter section 103 employs a two phase topology with two high current paths (phases A and B) each having input capacitance 107, a series FET 109, a synchronous rectifier FET 111, gate drive circuitry 113, an inductor 115, output capacitance 117, and an output relay 119. The input capacitance 107 and the series FET 109 of the two phases are connected to an input path 121 as shown. The output relays 119 of the two phases are connected to an output path 123 as shown. The input capacitance 107 filters unwanted high frequency noise components. The output capacitance 117 filters the current flowing from the inductor in the discharge state with the series FET 109 turned OFF and the synchronous rectifier FET 111 turned ON. The output capacitance 117 also provides low impedance for transient load current changes, thus reducing steady-state output ripple.

An input connector 125 provides for supply of the positive (+) and negative (−) DC voltage signals generated by the PV array 3 of FIG. 1. Input reservoir capacitors 127 are connected between these two DC voltage signals via the input connector 125. The positive (+) terminal of the connector 125 and the positive terminal of the input reservoir capacitors 127 are connected to the input path 121 of the buck converter section 103 as shown. The input reservoir capacitors 127 are charged in the charging state (when the series FET 109 for the two phases is OFF) and discharged in the discharging state (when the series FET 109 for the two phases is OFF and the synchronous rectifier FET 111 for the two phases is ON). The input reservoir capacitors 127 witness pulsed current with an amplitude equal to the load current. It is common practice to select the input reservoir capacitance with an RMS current rating more than half the maximum current load. If multiple capacitors are paralleled, the RMS current for each input reservoir capacitor should be total current divided by the number of input reservoir capacitors.

The output path 123 of the buck converter section 103 is connected to the positive (+) terminal of an output connector 127. The negative (−) terminal of the output connector 127 is grounded as shown. The output connector 127 provides for supply of positive (+) and negative (−) DC voltage signals generated by the buck converter section 103 to the DC load of FIG. 1, which can be battery bank and/or an DC-AC Inverter or other DC load.

Power supply circuitry 129 can be connected to the positive (+) terminal of the output connector 127 as shown. The power supply terminal transforms the DC voltage signal carried by the positive (+) terminal of the output connector 127 to internal bias voltage levels for supply to electrical components of the converter 100 as needed. Output protection circuitry 129 can also be provided between the positive (+) and negative (−) terminals of the output connector 127 to provide for overvoltage protection and possibly backflow current protection.

The microcontroller 105 supplies PWM control signals to the gate drive circuitry 113A, 113B of the two phases via control lines 141A, 141B. These PWM control signals effectuate desired control over the duty cycle of the charging state of the series FETs 109A, 109B for the two phases. The gate drive circuitry 113A, 113B for the two phases also controls the operation of the synchronous rectifier FETS 111A, 111B for the two phases based upon the PWM control signals supplied thereto. In the preferred embodiment, the series FETs 109A, 109B and the synchronous rectifier FETs 111A, 111B of the two phases are switched at a frequency of 30 KHz or greater when combined in order to keep noise above human hearing

For battery charging operations (e.g., Bulk Charging, Absorption Charging, Float Charging), the microcontroller 105 controls duty cycle of the PWM control signals supplied to the gate drive circuitry 113A, 113B (and thus controls the duty cycle of the charging state of the series FETs 109A, 109B for the two phases) based upon the input voltage provided by the PV array, the output voltage level and the output current level supplied to the DC load (i.e., the battery bank), and the battery current produced by the battery bank. The input voltage is measured by the input voltage sense circuit 133, which supplies a signal representative of the input voltage to the microcontroller 105 via path 143 for conversion into digital form therein. The output voltage is measured by the output voltage sense circuit 135, which supplies a signal representative of the output voltage to the microcontroller 105 via path 145 for conversion into digital form therein. The output current is measured by the output current sense circuit 137, which supplies a signal representative of the output current to the microcontroller via path 147 for conversion into digital form therein. The battery current is measured either by an internal current sensing device such as a shunt resistor or hall effect device, or alternatively by an external shunt at the battery bank (not shown), which supplies a signal representative of the battery current to the microcontroller via connector 149 for conversion into digital form therein.

The microcontroller 105 can also measure and/or maintain information regarding other characteristics of the battery bank, such as temperature of the battery bank and the battery terminal voltage measured by Kelvin connections. In the exemplary embodiment, a temperature sensor at the battery bank supplies a signal representative of the battery bank temperature to the microcontroller 105 via connector 149 for conversion into digital form therein. Similarly, a Kelvin connection at the battery bank supplies a signal representative of the terminal voltage of the battery bank to the microcontroller 105 via connector 149 for conversion into digital form therein. The Kelvin connection allows for more accurate monitoring of the terminal voltage of the battery bank, especially during high current charging operations. In such high current charging operations, there can be a significant voltage drop across the output of the converter, which causes the output voltage sense circuit 135 to underestimate of the true battery voltage. The Kelvin bridge circuit eliminates these inaccuracies as it provides an accurate measurement of the terminal voltage of the battery bank during such high current charging operations. The high accuracy battery voltage measurements are used in the preferred embodiment to provide more accurate battery charging.

The microcontroller 105 also interfaces to a temperature sensor 153 internal to the system housing 101 to measure the internal temperature of the system housing 101. This temperature can be used to activate, deactivate and control the speed of a fan 155 that blows air from outside the system housing to the interior space of the system housing for cooling as is well known. The microcontroller 105 can also interface to a temperature sensor (not shown) to measure the temperature on the interior or of the heat sink. This temperature too can be used to control the speed of the fan 155 (or additional fans) for cooling as needed.

The microprocessor 105 also interfaces to a front panel display and/or LED 157 and user input buttons 159 for presenting status information to the user as well as carrying out user interaction and control. The front panel display and/or LED 157 preferably presents status indications of a multiplicity of parameters including PV voltage, PV current, battery voltage, charging current, charging status, energy harvest history, battery energy status, energy used, etc.

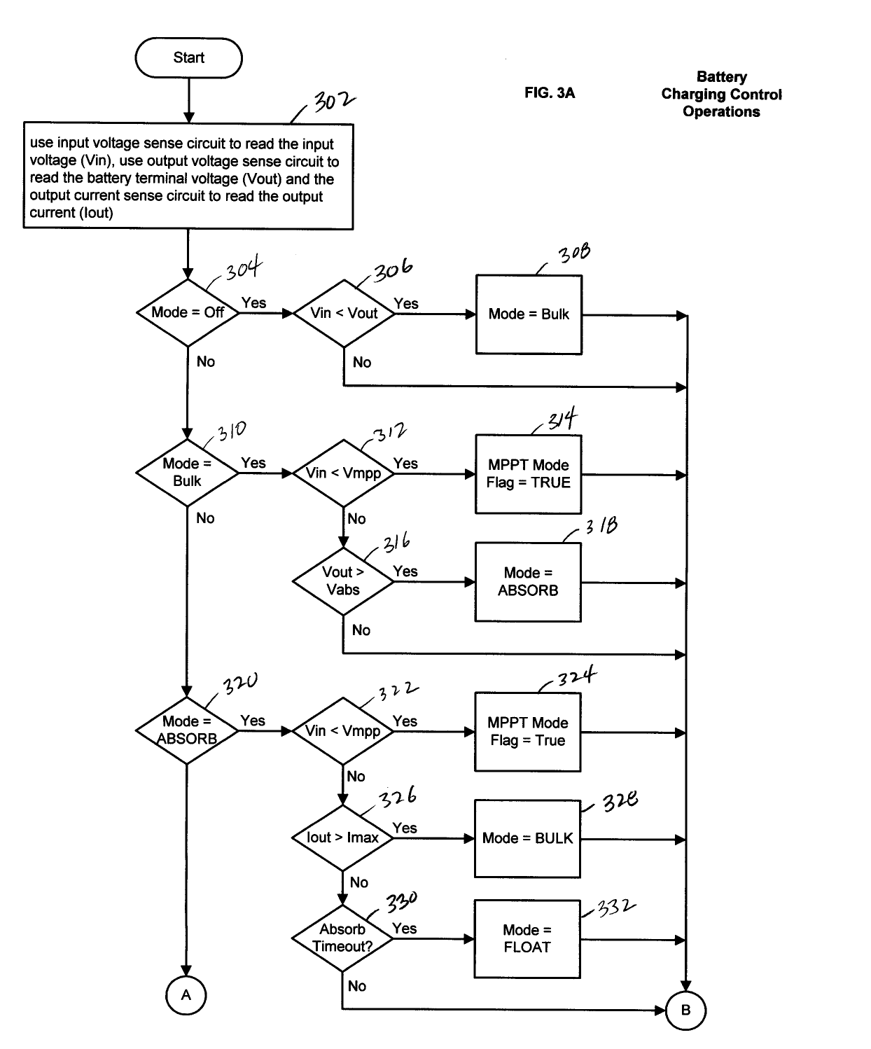

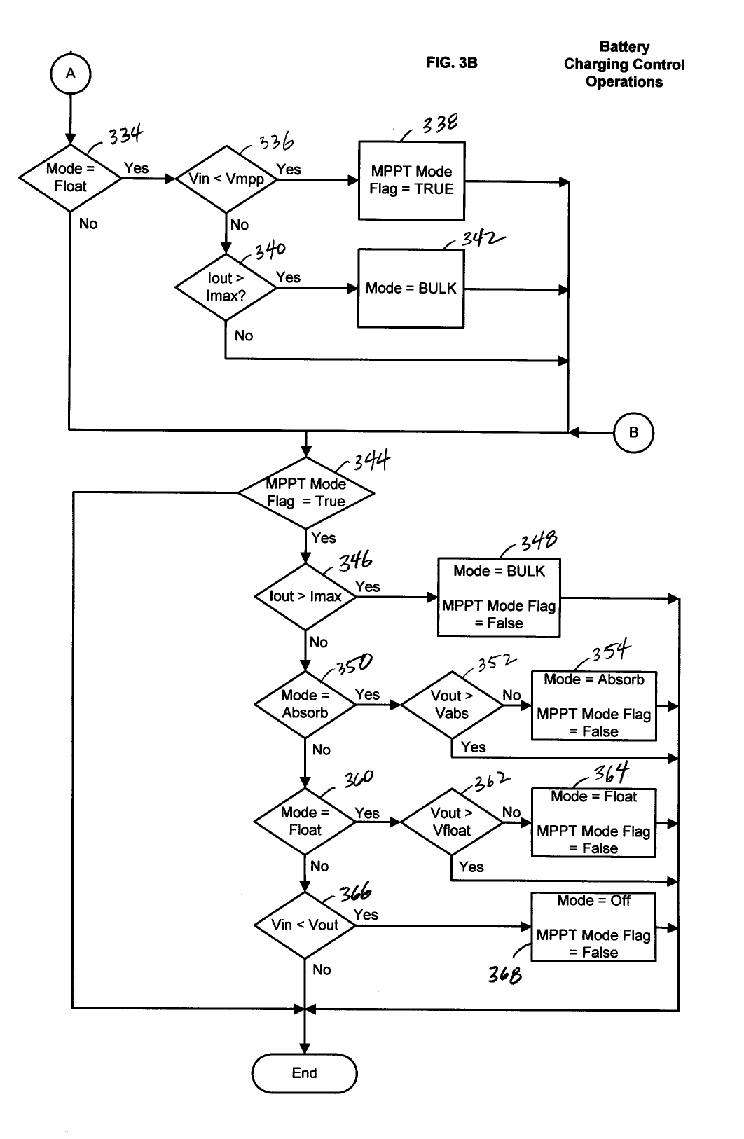

In accordance with the present invention, the charge controller 100 of FIG. 2 can be adapted for use in a wide range of applications, including the charging of a battery bank for the storage of electrical energy therein and/or the direct output of electrical energy to a DC-AC inverter and the like. FIGS. 3A and 3B, collectively, is a flow chart illustrating exemplary control operations carried out by the microcontroller 105 for automatic charging of a battery bank. The control operations employ five charging modes: Off, Bulk Charging Mode (for a highly discharged battery), Absorption Charging Mode, Float Charging Mode, and Maximum Power Point Tracking (MPPT) mode.

### Off Mode

In the Off mode, the microcontroller 105 opens the output relays 119 such that no current is passed through to the battery bank.

### Bulk Charging Mode

In the bulk charging mode, the microcontroller 105 regulates the output current (as measured by the output current sense circuit 137) such that it is at the maximum current limit of the converter (which is referred to herein as Imax and is designed to prevent overload). The maximum current Imax is preferably a parameter that is set and possibly updated by user input; alternatively, it can be stored as a constant value. The microcontroller 105 regulates the output current by controlling the duty cycle of the PMW control signals supplied to the gate drive circuitry 113A, 113B. The Bulk charging mode is used to charge a battery that is in a relatively low charge state.

### Absorption Charging Mode

In the absorption charging mode, the microcontroller 105 regulates the output voltage level (as measured by the output voltage sense circuit 135 or by the Kelvin connection), such that it is maintained at a predetermined absorption voltage level (referred to herein as Vabs). The predetermined absorption voltage level is preferably a parameter that is set and possibly updated by user input; alternatively, it can be stored as a constant value. The microcontroller 105 regulates the output voltage by controlling the duty cycle of the PMW control signals supplied to the gate drive circuitry 113A, 113B. The Absorption charging mode is used to charge a battery at a relatively high charge state.

### Float Charging Mode

In the float charging mode, the microcontroller 105 regulates the output voltage level (as measured by the output voltage sense circuit 135 or by the Kelvin connection), such that it is maintained at the predetermined float voltage level (referred to herein a Vfloat). The predetermined float voltage level is preferably a parameter that is set and possibly updated by user input; alternatively, it can be stored as a constant value. The microcontroller 105 regulates the output voltage by controlling the duty cycle of the PMW control signals supplied to the gate drive circuitry 113A, 113B. The float charging mode is used to charge a battery at a full or substantially full charge state

### MMPT Mode

In the MPPT mode, the microcontroller 105 regulates the input voltage level such that it is maintained at or near the peak power point on the current-voltage curve for the PV array 3 connected thereto. This voltage level is referred to herein as “Vmpp”. The microcontroller 105 regulates the input voltage by controlling the duty cycle of the PMW control signals supplied to the gate drive circuitry 113A, 113B.

The automatic battery charging operations of FIGS. 3A and 3B are performed on a periodic basis, preferably at least every 2 milliseconds or shorter. Such timing can be controlled by an interrupt timer or other timing circuitry. The operations are carried out using a state variable “Mode” that is set to correspond to the given operational mode, which can be either a predetermined value for the Off mode, a predetermined value for Bulk Charging, a predetermined value for Absorption Charging or a predetermined value for Float Charging. Because the MPPT mode can be used in conjunction with any one of the Bulk, Absorption and Float charging modes, a status flag (“MPPT mode FLAG”) is also used. The MPPT mode flag is set to true when the MPPT mode is active and set to false when the MPPT mode is inactive.

When the Mode variable is set, the microcontroller 105 automatically transitions to carry out the corresponding control operations for the particular mode as described above. In the Off mode, the microcontroller 105 opens the output relays 119 such that no current passes through from the input path 121 to the output path 123 and to the battery bank. In the Bulk charging mode, the microcontroller 105 regulates the output current such that it is at the maximum current limit Imax. In the Absorption charging mode, the microcontroller 105 regulates the output voltage level such that it is maintained at a predetermined absorption voltage level Vabs. In the Float charging mode, the microcontroller 105 regulates the output voltage level such that it is maintained at the predetermined float voltage level Vfloat.

When the MPPT mode flag is set to true, the MPPT mode operations override the charging mode operations (Bulk, Absorption or Float charging operations) as dictated by the Mode variable. Such override processing causes the microcontroller 105 to regulate the input voltage level such that it is maintained at or near the Vmpp value as described herein. When the MPPT mode flag is set to false, the override processing is avoided such that the charging mode operations dictated by the Mode variable are performed.

The operations begin in step 302 where the microcontroller 105 uses the input voltage sense circuit 133 to measure the input voltage (Vin), uses the output voltage sense circuit 135 to measure the output voltage (Vout), and uses the output current sense circuit 137 to measure the output current (lout). For reverse current protection, the output relays 119 are switched OFF in the event that the output current lout is less than a minimal threshold current, for example 2 amperes. The output relays 119 are switched ON for power conversion in the Bulk Charging, Absorption Charging, Float Charging and MPPT modes.

In step 304, the microcontroller 105 determines if the Mode variable is set to the “Off” value. If the determination of step 304 is false, the operations continue to step 310. If the determination of step 304 is true, the operations continue to step 306 where the microcontroller 105 checks whether the input voltage Vin is less than the output voltage Vout. If the decision of step 306 is true, the microcontroller 105 in step 308 sets the Mode variable to the “Bulk” value and the operations continue to step 344. If the decision of step 304 is false, the microcontroller 105 continues to step 344.

In step 310, the microcontroller 105 determines if the Mode variable is set to the “Bulk” value. If the determination of step 310 is false, the operations continue to step 320. If the determination of step 310 is true, the operations continue to step 312 where the microcontroller 105 checks whether the input voltage Vin is less than the maximum power point voltage Vmpp. If the decision of step 312 is true, the microcontroller 105 in step 314 sets the MPPT Mode flag to true and the operations continue to step 344. If the decision of step 312 is false, the microcontroller 105 continues to step 316 to check whether the output voltage Vout is greater than the absorption voltage Vabs. If the decision of step 316 is true, the microcontroller 105 in step 318 sets the Mode variable to the “Absorb” value and the operations continue to step 344. If the decision of step 316 is false, the operations continue to step 344.

In step 320, the microcontroller 105 determines if the Mode variable is set to the “Absorb” value. If the determination of step 320 is false, the operations continue to step 334. If the determination of step 320 is true, the operations continue to step 322 where the microcontroller 105 checks whether the input voltage Vin is less than the maximum power point voltage Vmpp. If the decision of step 322 is true, the microcontroller 105 in step 324 sets the MPPT Mode flag to true and the operations continue to step 344. If the decision of step 322 is false, the microcontroller 105 continues to step 326 to check whether the output current lout is greater than the maximum output current Imax. If the decision of step 326 is true, the microcontroller 105 in step 328 sets the Mode variable to the “Bulk” value and the operations continue to step 344. If the decision of step 326 is false, the operations continue to step 330 to check if an absorption timer has expired. The absorption timer is automatically set when the microcontroller 105 transitions from the Bulk mode to the Absorption mode. The initial absorption timer value is preferably a parameter that is set and possibly updated by user input; alternatively, it can be stored as a constant value. If the test of step 330 is true, the microcontroller 105 in step 332 sets the Mode variable to the “Float” value and the operations continue to step 344.

In step 334, the microcontroller 105 determines if the Mode variable is set to the “Float” value. If the determination of step 334 is false, the operations continue to step 344. If the determination of step 334 is true, the operations continue to step 336 where the microcontroller 105 checks whether the input voltage Vin is less than the maximum power point voltage Vmpp. If the decision of step 336 is true, the microcontroller 105 in step 338 sets the MPPT Mode flag to true and the operations continue to step 344. If the decision of step 336 is false, the microcontroller 105 continues to step 346 to check whether the output current lout is greater than the maximum output current Imax. If the decision of step 346 is true, the microcontroller 105 in step 342 sets the Mode variable to the “Bulk” value and the operations continue to step 344.

In step 344, the microcontroller 105 checks whether the MPPT status flag is set to true. If the test of step 344 fails, the operations end. If the test of step 344 is true, the operations continue in step 346 to check whether the output current lout is greater than the maximum output current Imax. If the decision of step 346 is true, the microcontroller 105 in step 348 sets the Mode variable to the “Bulk” value and clears the MPPT Mode flag to false and the operations end. If the decision of step 346 is false, the operations continue to step 350.

In step 350, the microcontroller 105 checks whether the Mode variable is set to the “Absorb” value. If the test of step 350 is false, the operations continue to step 360. If the test of step 350 is true, the microcontroller 105 continues to step 352 to check whether the output voltage is greater than the Vabs. If so, the operations continue to step 354 to set the Mode variable to the “Absorb” value and clears the MPPT Mode flag to false and the operations end. If not, the operations end.

In step 360, the microcontroller 105 checks whether the Mode variable is set to the “Float” value. If the test of step 360 is false, the operations continue to step 366. If the test of step 360 is true, the microcontroller 105 continues to step 362 to check whether the output voltage is greater than Vfloat. If so, the operations continue to step 364 to set the Mode variable to the “Float” value and clears the MPPT Mode flag to false and the operations end. If not, the operations end.

In step 366, the microcontroller 105 checks whether the input voltage is greater than the output voltage. If so, the Mode variable is set to the “Off” value and clears the MPPT Mode flag to false and the operations end. If not, the operations end.

In each one of the Bulk Charging Mode, Absorption Charging Mode and the Float Charging mode, the PV array may not be able to supply the required power to achieve the desired voltage or current limits set by the charging operations. Under these conditions, the microcontroller 105 transitions to the MPPT mode. For example, for the Bulk Charging Mode, the microcontroller 105 automatically transitions to the MPPT mode in steps 312 and 314. In the Absorption Charging Mode, the microcontroller 105 automatically transitions to the MPPT mode in steps 322 and 324. In the Float Charging Mode, the microcontroller 105 automatically transitions to the MPPT mode in steps 336 and 338.

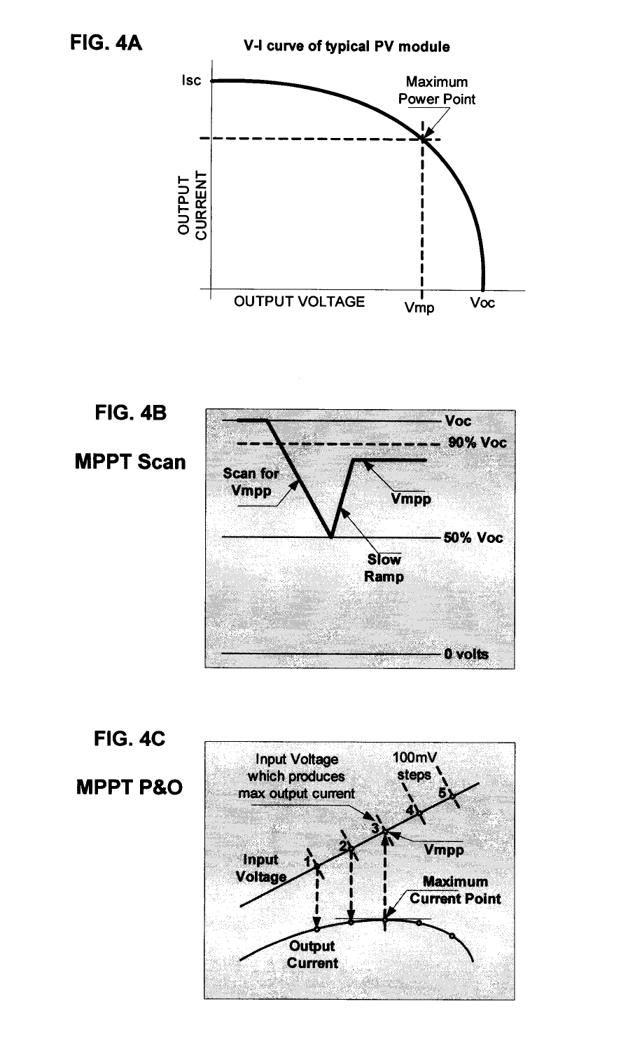

For the MPPT mode, the microcontroller 105 regulates the input voltage level such that it is maintained at or near the peak power point on the current-voltage curve for the PV array as shown graphically in FIG. 4A. This voltage level is referred to herein as “Vmpp”. In the preferred embodiment, the Vmpp voltage level is derived from a scanning step as well as perturbation and observation steps. The scanning step is graphically illustrated in FIG. 4B and the perturbation and observation steps are graphically illustrated in FIG. 4C.

The scanning step establishes the open circuit voltage of the PV array together with an initial value for Vmpp. The perturbation and observation steps vary the input voltage to multiple sample points about the initial “Vmpp” value established by scanning and measures the output current at each sample point. The sample point with maximum output current is selected as the new “Vmpp” value.

In the illustrative embodiment, the scanning steps include the following sequence of operations:

i) the duty cycle of the converter section 103 is reduced to zero such that the switching devices remain OFF for a predetermined sampling period such that the input voltage sense circuit measures the open circuit voltage Voc of the PV panel. The microcontroller 105 reads this measurement via input path 143.

ii) the microcontroller 105 sweeps the input voltage over sample points within a predetermined voltage range based on the Voc measured in i); for example, the predetermined voltage range can be from Voc to 50% to 60% Voc (or to 130% of the battery terminal voltage, whichever is greater); in the preferred embodiment, the microcontroller 105 ramps down the input voltage on 1 volt steps every 400 milliseconds.

iii) at each one of the sample points in ii), the microcontroller 105 measures and stores the output current; and

iv) the microcontroller 105 analyzes the stored output current values over the sample points of the scan to identify the sample point with the maximum output current value. This highest output current value, denoted Impp establishes the initial voltage level “Vmpp” that provides peak power; and

v) the microcontroller 105 then slowly increases the input voltage level from the floor (low point) of the scan to the “Vmpp” level. The slow adjustment to the input voltage level (which is preferably on the order of 1 volt every 200 milliseconds) prevents rapid changes in current which can cause overshoot and errors in the control routine.

In alternative embodiments, it is contemplated that the scanning operations can start at the bottom of the range and sweep the input voltage by ramping up the input voltage. At the top of the range, the microcontroller can then ramp down the input voltage to the Vmpp voltage level.

In the illustrative embodiment, the perturbation and observation steps include the following sequence of operations:

i) the output current is measured a number of times (for example, 128 times in one embodiment) to reduce any inaccuracies due to noise and the average is stored as the maximum current point Impp (which is labeled P3 for purposes of illustration in FIG. 4C);

ii) the input voltage is reduced by 200 mV by adjusting the duty cycle of the PWM control signals supplied to the gate driver circuitry 113 and the output current is again measured many times, averaged and recorded (this point is labeled P1 for purposes of illustration in FIG. 4C);

iii) the input voltage is increased by 100 mV by adjusting the duty cycle of the PWM control signals supplied to the gate driver circuitry 113 and the output current is again measured many times, averaged and recorded (this point is labeled P2 for purposes of illustration in FIG. 4C);

iv) the input voltage is increased to 100 mV above the voltage value for the Impp point in i) by adjusting the duty cycle of the PWM control signals supplied to the gate driver circuitry 113 and the current is again measured many times, averaged and recorded (this point is labeled P4 for purposes of illustration in FIG. 4C);

v) the input voltage is increased to 100 mV by adjusting the duty cycle of the PWM control signals supplied to the gate driver circuitry 113 and the current is measured again many times, averaged and recorded (this point is labeled P5 for purposes of illustration in FIG. 4C); and

vi) The stored output current values for the steps i)-v) above are processed to select the highest output current value and the voltage value for that selected sample point is stored as the new Vmpp value.

Note that for the perturbation and observation step described above, the number of sample points, the voltage difference between the sample points, and the order in which the sample points are measured can be changed as desired and are proved for illustrative purposes.

Also note that for the perturbation and observation step described above, one of the sample points is the Vmpp point itself, multiple sample points are provided at voltage levels above the Vmpp point, and multiple sample points are provided at voltage levels below the Vmpp point. Such sampling quickly locates the maximum power point and thus reduces the processing time and delays associated therewith. Such reduction in processing time improves the efficiency of the power conversion process, especially in dynamic conditions (e.g., changing sunlight due to moving cloud cover and the like).

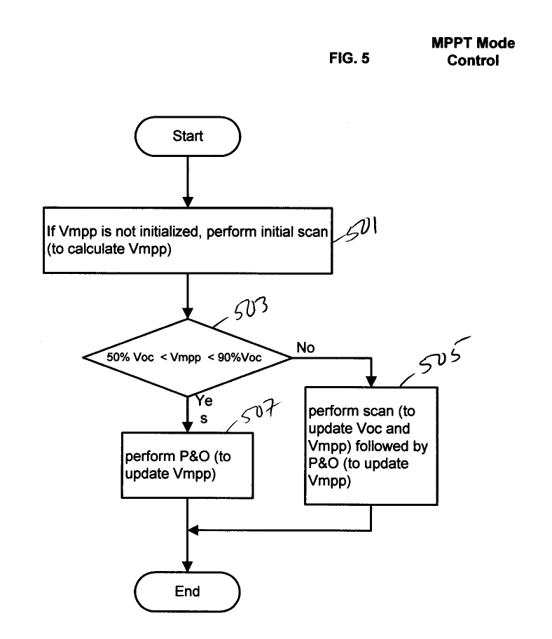

FIG. 5 is a flow chart illustrating exemplary control operations that are carried out by the microcontroller 105 in order to calculate and update the Vmpp value as described herein. Such operations are preferably performed on a periodic basis when the MPPT mode flag is activated in accordance with the operations of FIG. 3 as described above. Such timing can be controlled by an interrupt timer or other timing circuitry. In the illustrative embodiment, the operations of FIG. 5 are performed on a period basis every 2 milliseconds or shorter, which corresponds to a frequency of 500 Hz or greater. In this manner, the Vmpp values are updated at least every 2 milliseconds or less (or at a frequency of 500 Hz or greater), which enhances the efficiency of the conversion process especially during dynamic conditions.

In step 501, the microcontroller 105 checks whether the Vmpp has been initialized. If no, the microcontroller 105 performs as initial scanning step as described above with respect to FIG. 5B. This scanning step calculates the initial Vmpp value for the MPPT mode processing.

In step 503, the microcontroller 105 checks whether the input voltage Vin is within a predetermined voltage range (for example between 50% Voc and 90% Voc. If not, the operations continue to step 505 to perform a scanning step as described above with respect to FIG. 5B followed by a perturbation and observation step as described above with respect to FIG. 5C. The scanning of step 505 updates the open circuit voltage Voc and the Vmpp value, and the perturbation and observation of step 505 updates the Vmpp value. From step 505, the operations end.

If the results of step 503 indicate that the input voltage Vin is within the predetermined voltage range, the operations continue to step 507 to perform a perturbation and observation step as described above with respect to FIG. 5C. The perturbation and observation of step 507 updates the Vmpp value. From step 507, the operations end.

There have been described and illustrated herein an embodiment of charge controller for solar applications and methods of operating same. While a particular embodiment of the invention have been described, it is not intended that the invention be limited thereto, as it is intended that the invention be as broad in scope as the art will allow and that the specification be read likewise. Thus, while particular control operations (including particular control states and transitions between control states) have been disclosed, it will be appreciated that other control operations can be used as well. In addition, while particular buck-type converter topologies have been disclosed, it will be understood that the general control operations described herein can be used with other PWM-controlled converter topologies or other non-PWM converter topologies. Also, while it is preferred that the control operations of the charge controller be carried out by a microcontroller element, it will be recognized that other control elements and control systems can be used (such as a microprocessor, a digital signal processor, an ASIC, a CPLD, an FPGA, or other digital logic device). It is preferably that the control operations be realized as a program of instructions that are loaded into the firmware of the microcontroller or other programmed logic device. Furthermore, while the embodiments described above utilize field effect transistors as switching devices, it will be understood that other switching devices such as IGBT insulated gate bipolar transistors can be similarly used. In addition, while particular solar applications have been disclosed, it will be understood that the charge controller described herein can be adapted for other energy conversion applications such as wind energy harvesting, wave-energy harvesting, hydroelectric energy harvesting, thermoelectric energy harvesting, etc. It will therefore be appreciated by those skilled in the art that yet other modifications could be made to the provided invention without deviating from its spirit and scope as claimed.

What is claimed is:

1. A power converter comprising:
an input interface that receives input DC electrical signals;
a converter section for converting the input DC electrical signals to output DC electrical signals; and
control means operably coupled to the converter section, the control means including means for operating the converter section at an estimated maximum power point of the input DC electrical signals, the estimated maximum power point derived by a control scheme that includes the following operations:
i) storing an input voltage level corresponding to the estimated maximum power point;
ii) varying the input voltage of the input DC electrical signals over a sequence of sample points from a first voltage level to a second voltage level, and deriving and storing an output current value of the output DC electrical signals at each sample point;
iii) selecting the maximum output current value from the output current values stored in ii) and identifying the particular input voltage level corresponding thereto; and
iv) varying the input voltage of the input DC electrical signals over a sequence of sample points from the second voltage level to the particular input voltage level identified in iii); and
v) updating the stored input voltage level corresponding to the estimated maximum power point to the particular input voltage level identified in iv).

2. A power converter according to claim 1, wherein:
for each given sample point in ii), the output current value for the sample point is derived by averaging a plurality of output current measurements at the given sample point.

3. A power converter according to claim 1, wherein:
the control scheme measures the open circuit voltage of the input DC electrical signals, and at least one of the first and second voltage levels are derived from the measured open circuit voltage.

4. A power converter according to claim 1, wherein:
the varying of iv) changes the input voltage of the input DC electrical signals at a rate not greater than 100 millivolts per second.

5. A power converter according to claim 1, wherein:
the converter section comprises a buck converter topology having input reservoir capacitance, at least one series switching element, at least one inductor, and gate drive circuitry that selectively switches the at least one series switching element between ON and OFF states in response to pulse width modulation control signals supplied thereto, the control means operably coupled to the gate drive circuitry for varying the duty cycle of the pulse width modulation control signals supplied to the gate drive circuitry in order to vary the input voltage level of the input DC electrical signals.

6. A power converter according to claim 4, wherein:
the buck converter topology includes at least one synchronous rectifier switching element that is operably coupled to the gate drive circuitry, the gate drive circuitry selectively switching the at least one synchronous rectifier switching element between ON and OFF states in response to the pulse width modulation control signals supplied thereto.

7. A power converter according to claim 6, wherein:
the buck converter topology includes two phases that are controlled by the control means to operate 180 degrees out of phase with respect to one another.

8. A power converter according to claim 6, wherein:
the at least one series switching element and the at least one synchronous rectifier switching element are switched ON and OFF at a frequency greater than 30 Hz.

9. A power converter according to claim 1, wherein:
the control scheme includes an MPPT charging mode, wherein during the MPPT charging mode the control means regulates the input voltage of the input DC electrical signals such that it is maintained at the input voltage level corresponding to the estimated maximum power point as stored by the control scheme.

10. A power converter according to claim 9, wherein:
the control scheme includes at least the following additional modes of operation:
a bulk charging mode that is automatically invoked to charge a battery that is in a relatively low charge state, wherein during the bulk charging mode the control means regulates the output current of the output DC electrical signals such that it is at a predetermined maximum current limit;
an absorption charging mode that is automatically invoked to charge a battery at a relatively high charge state, wherein during the absorption charging mode the control means regulates the output voltage of the output DC electrical signals such that it is maintained at a predetermined absorption charging mode voltage level; and
a float charging mode that is automatically invoked to charge a battery at a full or substantially full charge state, wherein during the absorption charging mode the control means regulates the output voltage of the output DC electrical signals such that it is maintained at a predetermined float charging mode voltage level; and

11. A power converter according to claim 10, wherein:
the control means automatically transitions from the bulk charging mode to the MPPT charging mode upon determination that the input voltage level of the input DC electrical signals is less than the input voltage level corresponding to the estimated maximum power point as stored by the control scheme.

12. A power converter according to claim 10, wherein:
the control means automatically transitions from the MPPT charging mode to the bulk charging mode upon determination that the output current of the output DC electrical signals is greater than the predetermined maximum current limit.

13. A power converter according to claim 10, wherein:
the control means automatically transitions from the absorption charging mode to the MPPT charging mode upon determination that the input voltage level of the input DC electrical signals is less than the input voltage level corresponding to the estimated maximum power point as stored by the control scheme.

14. A power converter according to claim 10, wherein:
the control means automatically transitions from the MPPT charging mode to the absorption charging mode upon determination that the output voltage of the output DC electrical signals is greater than the predetermined absorption charging mode voltage level.

15. A power converter according to claim 10, wherein:
the control means automatically transitions from the float charging mode to the MPPT charging mode upon determination that the input voltage level of the input DC electrical signals is less than the input voltage level corresponding to the estimated maximum power point as stored by the control scheme.

16. A power converter according to claim 10, wherein:
the control means automatically transitions from the MPPT charging mode to the float charging mode upon determination that the output voltage of the output DC electrical signals is greater than the predetermined float charging mode voltage level.

17. A power converter according to claim 1, wherein:
the control scheme includes operations that perturbate around the input voltage level corresponding to the estimated maximum power point for adjustment thereof.

18. A power converter comprising:
an input interface that receives input DC electrical signals;
a converter section for converting the input DC electrical signals to output DC electrical signals; and
control means operably coupled to the converter section, the control means including means for operating the converter section at an estimated maximum power point of the input DC electrical signals, the estimated maximum power point derived by a control scheme that includes the following:
i) storing an input voltage level corresponding to the estimated maximum power point;
ii) varying the input voltage of the input DC electrical signals over a number of sample points around the input voltage level stored in i), and deriving and storing an output current value of the output DC electrical signals at each sample point;
iii) selecting the maximum output current value from the output current values stored in ii) and identifying the particular input voltage level corresponding thereto; and
iv) updating the stored input voltage level corresponding to the estimated maximum power point to the particular input voltage identified in iii).
wherein the number of sample points in ii) include a first plurality of sample points at input voltage values less than the input voltage level stored in i) and a second plurality of sample points at input voltage values greater than the input voltage level stored in i).

19. A power converter according to claim 18, wherein:
the number of sample points in ii) include the input voltage level stored in i).

20. A power converter according to claim 18, wherein:
for each given sample point in ii), the output current value for the sample point is derived by averaging a plurality of output current measurements at the given sample point.

21. A power converter according to claim 18, wherein:
the voltage differences between the sample points of ii) is on the order of 100 millivolts.

22. A power converter according to claim 18, wherein:
the transformer section comprises a buck converter topology having input reservoir capacitance, at least one series switching element, at least one inductor, and gate drive circuitry that selectively switches the at least one series switching element between ON and OFF states in response to pulse width modulation control signals supplied thereto, the control means operably coupled to the gate drive circuitry for varying the duty cycle of the pulse width modulation control signals supplied to the gate drive circuitry in order to vary the input voltage level of the input DC electrical signals.

23. A power converter according to claim 22, wherein:
the buck converter topology includes at least one synchronous rectifier switching element that is operably coupled to the gate drive circuitry, the gate drive circuitry selectively switching the at least one synchronous rectifier switching element between ON and OFF states in response to the pulse width modulation control signals supplied thereto.

24. A power converter according to claim 23, wherein:
the buck converter topology includes two phases that are controlled by the control means to operate 180 degrees out of phase with respect to one another.

25. A power converter according to claim 23, wherein:
the at least one series switching element and the at least one synchronous rectifier switching element are switched ON and OFF at a frequency greater than 30 Hz.

26. A power converter according to claim 18, wherein:
the control scheme includes an MPPT charging mode, wherein during the MPPT charging mode the control means regulates the input voltage of the input DC electrical signals such that it is maintained at the input voltage level corresponding to the estimated maximum power point as stored by the control scheme.

27. A power converter according to claim 26, wherein:
the control scheme includes at least the following additional modes of operation:
a bulk charging mode that is automatically invoked to charge a battery that is in a relatively low charge state, wherein during the bulk charging mode the control means regulates the output current of the output DC electrical signals such that it is at a predetermined maximum current limit;
an absorption charging mode that is automatically invoked to charge a battery at a relatively high charge state, wherein during the absorption charging mode the control means regulates the output voltage of the output DC electrical signals such that it is maintained at a predetermined absorption charging mode voltage level;
a float charging mode that is automatically invoked to charge a battery at a full or substantially full charge state, wherein during the absorption charging mode the control means regulates the output voltage of the output DC electrical signals such that it is maintained at a predetermined float charging mode voltage level; and

28. A power converter according to claim 27, wherein:
the control means automatically transitions from the bulk charging mode to the MPPT charging mode upon determination that the input voltage level of the input DC electrical signals is less than the input voltage level corresponding to the estimated maximum power point as stored by the control scheme.

29. A power converter according to claim 27, wherein:
the control means automatically transitions from the MPPT charging mode to the bulk charging mode upon determination that the output current of the output DC electrical signals is greater than the predetermined maximum current limit.

30. A power converter according to claim 27, wherein:
the control means automatically transitions from the absorption charging mode to the MPPT charging mode upon determination that the input voltage level of the input DC electrical signals is less than the input voltage level corresponding to the estimated maximum power point as stored by the control scheme.

31. A power converter according to claim 27, wherein:
the control means automatically transitions from the MPPT charging mode to the absorption charging mode upon determination that the output voltage of the output DC electrical signals is greater than the predetermined absorption charging mode voltage level.

32. A power converter according to claim 27, wherein:
the control means automatically transitions from the float charging mode to the MPPT charging mode upon determination that the input voltage level of the input DC electrical signals is less than the input voltage level corresponding to the estimated maximum power point as stored by the control scheme.

33. A power converter according to claim 27, wherein:
the control means automatically transitions from the MPPT charging mode to the float charging mode upon determination that the output voltage of the output DC electrical signals is greater than the predetermined float charging mode voltage level.

34. A power converter according to claim 18, wherein:
the control scheme includes operations that vary the input voltage of the input DC signals over a predetermined range of input voltage values in order to adjust the input voltage level corresponding to the estimated maximum power point.

35. A power converter comprising:
an input interface that receives input DC electrical signals;
a converter section for converting the input DC electrical signals to output DC electrical signals; and
control means operably coupled to the converter section, the control means including means for operating the converter section at an estimated maximum power point of the input DC electrical signals, the estimated maximum power point derived by a control scheme that updates an input voltage level corresponding to the estimated maximum power point at a frequency of at least 500 Hz.

36. A power converter according to claim 35, wherein:
the converter section comprises a buck converter topology having input reservoir capacitance, at least one series field effect transistor, at least one inductor, and gate drive circuitry that selectively switches the at least one series switching element between ON and OFF states in response to pulse width modulation control signals supplied thereto, the control means operably coupled to the gate drive circuitry for varying the duty cycle of the pulse width modulation control signals supplied to the gate drive circuitry in order to vary the input voltage level of the input DC electrical signals.

37. A power converter according to claim 36, wherein:
the buck converter topology includes at least one synchronous rectifier switching element that is operably coupled to the gate drive circuitry, the gate drive circuitry selectively switching the at least one synchronous rectifier switching element between ON and OFF states in response to the pulse width modulation control signals supplied thereto.

38. A power converter according to claim 37, wherein:
the buck converter topology includes two phases that are controlled by the control means to operate 180 degrees out of phase with respect to one another.

39. A power converter according to claim 37, wherein:
the at least one series switching element and the at least one synchronous rectifier switching element are switched ON and OFF at a frequency greater than 30 Hz.

40. A power converter according to claim 35, wherein:
the control scheme includes an MPPT charging mode, wherein during the MPPT charging mode the control means regulates the input voltage of the input DC electrical signals such that it is maintained at the input voltage level corresponding to the estimated maximum power point as updated by the control scheme.

41. A solar electric generator system comprising:
a photovoltaic array;
a DC load; and
the power converter of claim 1 operably coupled between the photovoltaic array and the DC load, the power converter adapted to transform the DC electrical signals generated by the photovoltaic array into DC output signals suitable for supply to the DC load.

42. A solar electric generator system according to claim 41, wherein:
the DC load comprises at least one battery.

43. A solar electric generator system according to claim 41, wherein:
the DC load comprises a DC-AC power inverter.

44. A solar electric generator system comprising:
a photovoltaic array;
a DC load; and
the power converter of claim 18 operably coupled between the photovoltaic array and the DC load, the power converter adapted to transform the DC electrical signals generated by the photovoltaic array into DC output signals suitable for supply to the DC load.

45. A solar electric generator system according to claim 44, wherein:
the DC load comprises at least one battery.

46. A solar electric generator system according to claim 44, wherein:
the DC load comprises a DC-AC power inverter.

47. A solar electric generator system comprising:
a photovoltaic array;
a DC load; and
the power converter of claim 35 operably coupled between the photovoltaic array and the DC load, the power converter adapted to transform the DC electrical signals generated by the photovoltaic array into DC output signals suitable for supply to the DC load.

48. A solar electric generator system according to claim 47, wherein:
the DC load comprises at least one battery.

49. A solar electric generator system according to claim 47, wherein:
the DC load comprises a DC-AC power inverter.
